(19) United States
(12) Patent Application Publication
(10) Pub. No.: US 2010/0059677 A1
(43) Pub. Date: Mar. 11, 2010

(54) Aspheric Lenses for Imaging

(76) Inventors: Rainer Leonhardt, Auckland (NZ); Yat Hei Lo, Auckland (NZ)

Correspondence Address: DANN, DORFMAN, HERRELL & SKILLMAN, 1601 MARKET STREET, SUITE 2400, PHILADELPHIA, PA, 19103-2307, US

(21) Appl. No.: 12/557,052

(22) Filed: Sep. 10, 2009

Related U.S. Application Data
(60) Provisional application No. 61/095,758, filed on Sep. 10, 2008.

(51) Int. Cl. H01L 31/0232; H01L 31/09; G02B 13/14

(52) U.S. Cl. 250/330; 250/353; 359/356

(57) ABSTRACT

A lens for Terahertz imaging that has a transparent body defining at least a first and a second lens surface. The lens body is arranged such that light incident to the lens refracts at the first lens surface, propagates through the body to the second lens surface and refracts at the second lens surface. The angle of deviation of light at the first lens surface substantially equals the angle of deviation of light at the second lens surface.

### REFERENCE TO PRIOR APPLICATION

This application claims the benefit of U.S. Provisional Application No. 61/095,758, filed Sep. 9, 2008 the entirety of which is incorporated herein by reference.

### FIELD OF THE INVENTION

The present invention broadly relates to lenses and high resolution imaging and in particular to high resolution lenses for Terahertz imaging.

### BACKGROUND TO THE INVENTION

Over recent years there have been many new developments in the Terahertz (THz) region. Techniques such as spectroscopy, package inspection, biological investigation have advanced considerably. Most research is centered on high power emitters, quantum cascade lasers, and improving detection performance. However, little attention has been paid to improving imaging performance for THz imaging applications.

Imaging of THz waves is usually achieved using off-axis parabolic mirrors (OAPMs). Spherical lenses are not appropriate because of the large beam diameters associated with THz radiation. Due to the much larger wavelength, the spatial resolution (which is directly related to the focal spot size) is limited. To achieve small spot sizes, one must employ short focal lengths (˜cm). The wavelength then becomes comparable to this length and near-field optics has to be considered.

The traditional approach of using OAPM for imaging is diffraction limited. OAPMs are also susceptible to aberrations once misaligned. In addition, alignment is always difficult as the direction of the optical axis changes upon reflection off the mirror. The numerical aperture (NA) is also limited. For high NAs the incident beam overlaps with the focal spot.

### SUMMARY OF THE INVENTION

It is an object of the present invention to provide a lens for Terahertz imaging that improves on other lens designs.

In a first aspect the invention broadly consists in lens for Terahertz imaging comprising a transparent body defining at least a first and a second lens surface, the body arranged such that light incident to the lens refracts at the first lens surface, propagates through the body to the second lens surface and refracts at the second lens surface, wherein the angle of deviation of light at the first lens surface substantially equals the angle of deviation of light at the second lens surface.

Preferably the first lens surface of the transparent body is defined by a first surface contour and the second lens surface of the transparent body is defined by a second surface contour.

Preferably the first surface contour and the second surface contour are numerically calculated to form a symmetric-pass lens.

Preferably the transparent body is made of a highly transparent polymer.

In another aspect the invention broadly consists in a method of producing a lens comprising:
selecting a lens focal length,
selecting a lens numerical aperture,
selecting a lens diameter,
numerically deriving the coordinates of a first lens surface in relation to the coordinates of a second lens surface such that the angle of deviation of light at the first lens surface will substantially equal the angle of deviation of light at the second lens surface, and
cutting a transparent body of material having first and second surfaces according to the first and second lens surface coordinates, the surfaces arranged such that light incident to the lens will propagate from the first surface to the second surface.

In another aspect the invention broadly consists in a Terahertz imaging system comprising:
a Terahertz light source, the light source arranged to output light to a lens, the lens further comprising a transparent body defining at least a first and a second lens surface, the body arranged such that light incident to the lens refracts at the first lens surface, propagates through the body to the second lens surface and refracts at the second lens surface, wherein the angle of deviation of light at the first lens surface substantially equals the angle of deviation of light at the second lens surface, and
a Terahertz light detector, the detector arranged to receive light from the lens.

It is not the intention to limit the scope of the invention to the above-mentioned examples only. As would be appreciated by a skilled person in the art, many variations are possible without departing from the scope of the invention.

### BRIEF DESCRIPTION OF THE DRAWINGS

The invention will be further described by way of example only and without intending to be limiting with reference to the following drawings, wherein:

FIG. 1a shows a planar-hyperbolic lens.

FIG. 1b shows an elliptical-aspheric lens.

FIG. 1c shows a symmetric-pass lens according to a preferred embodiment of the invention.

FIG. 2a shows a reflection losses, absorption losses and beam shaping parameters. FIG. 2b shows a δ(r) curve.

FIG. 3 shows intensity profiles of three different lenses.

FIG. 4 shows an experimental setup for measuring focal spot sizes.

FIG. 5a shows half-plane scan results for the planar-hyperbolic lens at 0.7 THz.

FIG. 5b shows half-plane scan results for the elliptical-aspheric lens at 0.7 THz.

FIG. 5c shows half-plane scan results for the symmetric-pass lens of the present invention at 0.7 THz.

FIG. 6a shows a double pinhole used as an image sample.

FIG. 6b shows imaging results of the planar-hyperbolic lens.

FIG. 6c shows imaging results of the elliptical-aspheric lens.

FIG. 6d shows imaging results of the symmetric-pass lens according to the preferred embodiments of the present invention.

### DETAILED DESCRIPTION OF PREFERRED EMBODIMENTS

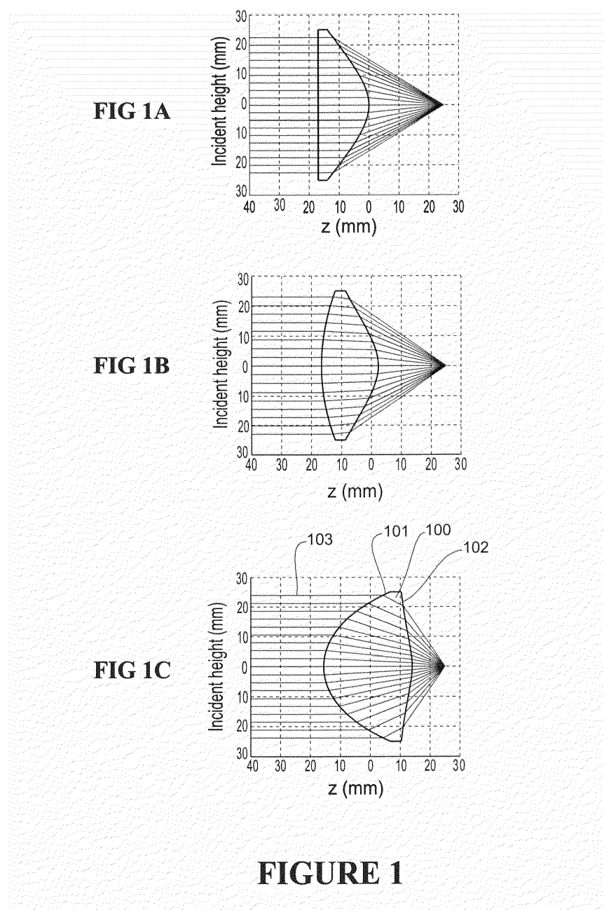

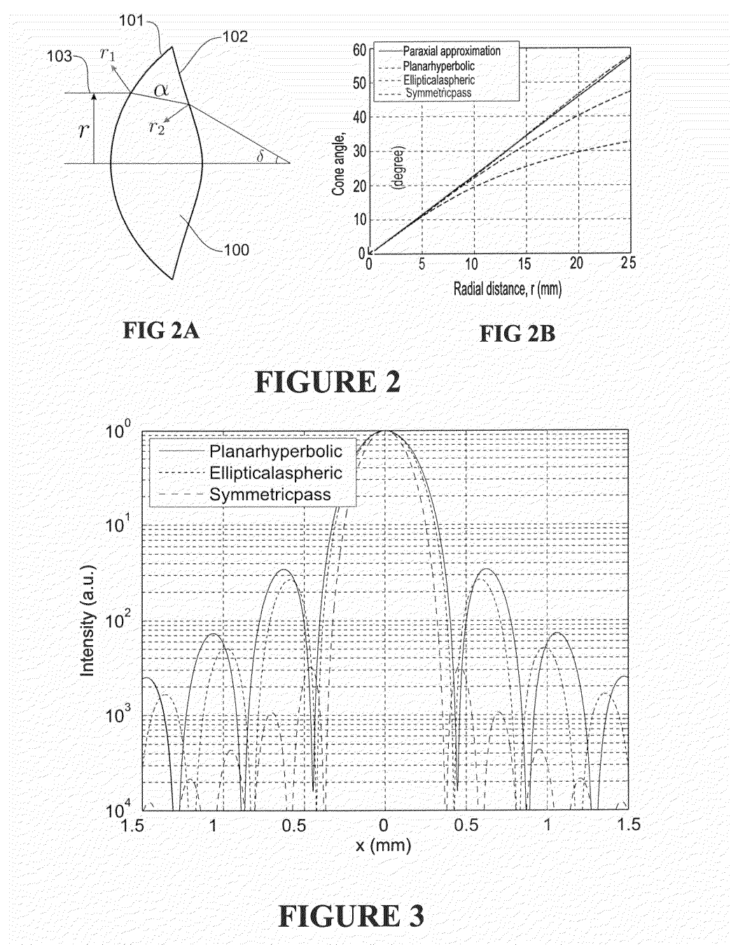

Referring to FIG. 1c and FIG. 2, in a preferred embodiment of the present invention, an lens comprises a transparent body 100 that defines a first lens surface 101 and a second lens surface 102. The body 100 is arranged to allow light 103 incident to the lens to refract at the first lens surface 101, propagate through the body 100 to the second lens surface 102 and refract at the second lens surface. The angle of deviation of light at the first lens surface 101 substantially equals the angle of deviation of light at the second lens surface 102.

The lens of the preferred embodiment of the present invention is primarily designed to operate in a Terahertz imaging system. A Terahertz imaging system comprises a Terahertz light source, the lens and a Terahertz radiation detector. The light source is arranged to output light to the lens, either directly or indirectly. The lens then resolves the incident light such that the detector can form an image. In a general Terahertz imaging system the lens is arranged to receive light generated by the source and subsequently reflected or transmitted from other optical components or objects.

To produce a lens according to the preferred embodiment of the present invention one must select a desired lens focal length, select a desired lens numerical aperture, select a lens diameter, numerically derive the coordinates of the first lens surface contour in relation to the coordinates of the second lens surface contour such that the angle of deviation of light incident the first lens surface substantially equals the angle of deviation of light at the second lens surface.

When a numerical representation of the surface contours of the lens is calculated, one may proceed with cutting a transparent body of material to accord with the numerical representation of the first and second surfaces according to the first and second lens surface contours.

The profile of the lens of the present invention is determined by the principle that each ray from an incident beam experiences the same angle of deviation on both surfaces while passing through the lens. A lens having an equal angle of deviation is called a ‘symmetric pass’ lens. A symmetric pass lens minimises the overall reflection loss experienced by light propagating through the lens. There is, however, no analytical expression for both first and second surfaces. The entire lens profile is calculated numerically.

To simplify numerical derivation of the preferred lens surface contours, geometrical optics is used to define both the first lens surface and the second lens surface. The derivation relies on Fermat's principle where the entire wavefront from a collimated incident beam converges into a focal spot and each ‘ray’ travels the same optical distance. This ensures a lens design with no spherical aberration. Geometrical optics, however, does not provide an indication of the resultant focal spot size. In order to analyze the performance of different lens designs, Kirchhoff's Scalar Diffraction theory can be used to determine the different focal spot sizes.

The following procedural steps were used to generate the preferred lens:
1) Rays that are parallel to the optical axis were used as input rays to the lens.
2) The thickness of the lens was assumed to be zero at the edge of the lens, which is a distance D/2 (where D is the diameter of the lens) away from the optical axis. Choosing a point F as focal point on the optical axis, the path of the ray that hits the edge of the lens is clearly defined, and knowing the refractive index of the lens, using Snell's law and taking the symmetric pass (i.e. equal deviation at both surfaces) through the lens into account, the angles of incidence (and therefore the slopes) of the first and second surface of the lens at this point was calculated.
3) Having worked out the path for this ray and assuming an arbitrary plane P (which is perpendicular to the optical axis) in front of the lens, the optical path length lₒₚₜ for this outer-most ray from P to F was calculated. According to Fermat's principle the optical path length for all other rays is lₒₚₜ.
4) A ray is chosen that lies an infinitesimal distance □r closer to the optical axis than the previous ray. Using the slope of the of the first lens surface as calculated from the previous ray, the intersection of the new ray with the first lens surface can be calculated. Taking Snell's law, Fermat's principle, and the symmetric pass (i.e. equal deviation at both surfaces) through the lens into account, the path of the ray from the first surface via the second surface to the focal point F can be calculated.
5) Once the path of the ray had been calculated, the slope of the two lens surfaces at the intersection of this ray was determined.
6) Steps (4) and (5) are repeated until the ray hits the lens on the optical axis.
7) All the intersecting points on the first and second surface completely describe the two surfaces of the lens (as the lens possesses radial symmetry).
8) Using the paraxial part of the curve that shows the cone angle □ of the ray approaching the focal point versus the radial distance r of the incoming ray, the effective focal length f of the lens was calculated.
9) For a desired focal length f*, this process has to be repeated with different points F′ until the resulting focal length f matches the desired focal length f*.

The focal spot size is directly related to the spatial resolution of the imaging system. To determine the spot size Kirchhoff's Scalar Diffraction Theory can be used. Kirchhoff's Scalar Diffraction Theory is based on the near-field Huygens-Fresnel Principle, although it is derived by a different approach. As an integral algorithm, Kirchhoff's Scalar Diffraction Theory allows reasonably fast calculations with sufficient accuracy. The algorithm is based on the following equation:

$$Ep = {\int }_{S} \frac{K ( θ ) {ɛ}_{A}}{r} cos ( kr - w t - \frac{π}{2} ) d S$$

where Ep is the resultant electric field at point P as a result of all contributions from the incident wavefront; S is the input surface for the diffraction algorithm; ε_{A} is the amplitude of the input electric field on S; r is the distance between S and P; K(θ) is the obliquity factor.

To further increase the speed of simulations, geometrical optics can be applied to trace the beam from the incident plane to the second surface of the lens taking into account the effects of reflection, absorption and refraction. The beam profile at the second lens surface can be used as the input to the Kirchhoff's scalar diffraction algorithm. Since this is an integral calculation, the plane can be chosen where it is desirable to evaluate the output.

The preferred lens material is a highly transparent polymer such as Ultra High Molecular Weight Polyethylene (UHMWPE), ZEONEX, Picarin and TPX. However, other similar materials can also be used. UHMWPE has a measured refractive index of 1.5245 and an absorption coefficient of 0.0135 mm⁻¹. UHMWPE is suitable as a lens material for even ultra-broadband THz radiation due to the reasonably low absorption and negligible dispersion.

Compared to off-axis parabolic mirrors, the aspheric lenses of the present invention can have much larger numerical apertures. The lenses can also achieve sub-wavelength resolution. As all the parameters can be scaled with the wavelength, the novel concepts presented herein are also applicable to other regions of the electro-magnetic spectrum.

Further compared to off-axis parabolic mirrors, lenses are much easier to align, less susceptible to aberrations. Simply placing a lens on the optical axis with no tilt ensures proper alignment. While a parabolic surface is the only solution for a mirror to convert a plane wavefront into a spherical wavefront, a lens with its two surfaces allows an infinite number of solutions. Each solution will generate a different near-field pattern, and therefore the spatial resolution of the system will depend on the lens design.

### EXPERIMENTAL VERIFICATION

Three aspheric lenses were constructed to verify the advantages of the symmetric pass lens of preferred embodiment of the present invention. The lenses were milled on a computer-controlled lathe, resulting in a surface roughness of less than 30 μm (˜λ/10). For all of the lenses studied here, a focal length of 25 mm and a diameter of 50 mm was chosen. The focal length of the lenses is determined using the paraxial part of the beam.

Despite each lens having the same diameter and the same focal length, each lens show a different characteristic due to their different surface profiles. As all of the lenses produce spherical wavefronts, the only difference between the lenses is the amplitude distribution across the wavefront. The lens will affect this distribution in three different ways (see FIG. 2(a)): 1) reflection losses r₁(r) and r₂(r) at the two surfaces, 2) absorption losses α(r) within the lens, and 3) beam shaping δ(r) due to refraction. While the reflection and absorption losses should be taken into account, they only play a minor role in determining the focal spot size. All simulations were performed using a polarized Gaussian input beam with a FWHM of 25 mm at a frequency of 0.7 THz (corresponding to a wavelength of 0.43 mm). For such a beam the losses would reduce the beam power down to 75%, 74%, and 65% for the planar-hyperbolic, elliptical-aspheric and symmetric-pass lenses, respectively.

The most straight forward approach to design an aberration-free aspheric lens is to set the first surface to be flat, with all refraction occurring at the second surface. Once the focal length of the lens has been fixed, this method has no degree of freedom except for the thickness of the lens. The resultant second surface is hyperbolic. For this design the focal length is always equal to the distance from the tip of the lens (at the optical axis) to the focal spot.

FIG. 1(a) shows a planar-hyperbolic lens as used in the experimental verification. It should be noted that the angle between the incident beam and the asymptote to the hyperbola is per definition the critical angle where total internal reflection starts to occur. For lenses with high NAs the beam will suffer large reflection losses.

A lens can be also designed with the first surface to be curved. Choosing the first surface to be elliptical, an analytical solution for the second surface was derived. This allows for more degrees of freedom when designing, namely the curvature of the first surface. An elliptical first surface will generate a spherical wavefront within the lens material that would generate a focus at a distance f e. The second surface images this spherical wavefront to another spherical wavefront behind the lens.

FIG. 1(b) shows a design for the elliptical-aspheric lens where f e=202 mm was chosen.

The focal spot size depends mainly on the beam shaping δ(r). It is evident from FIG. 1 that for the different lens designs, the relation between the incident beam position and the angle it makes with the optics axis, the cone angle δ, is quite different. FIG. 2(b) shows the δ(r) relations for the three lens designs.

For a thin lens, where spherical surfaces are assumed and paraxial approximation is applied, the relation between δ(in radians) and r is simply linear. The gradient of the linear line is 1/f , where f is the focal length. For non-paraxial beams this relation becomes non-linear, and even for thin spherical lenses, spherical aberration occurs as well. It is clear from FIG. 2(b) that the planar-hyperbolic lens will give a narrow amplitude distribution after the lens, while the symmetric-pass lens will give the widest. As the focal plane is less than 100λ away from the lens, it is essential to use near-field theory to work out the precise intensity distribution in the focal plane.

While all the results presented here refer to the focal plane, the output in other planes was calculated to ensure that the focus is at the expected position. As the reflection losses are polarization dependent, the intensity profile in the focal plane is very slightly elliptical.

FIG. 3 shows the cross-sections of the intensity profiles of three different lenses on the axis that is perpendicular to the incident polarization. It can be clearly seen that the symmetric-pass lens not only gives the smallest FWHM but also has secondary diffraction maxima that are more than one order of magnitude lower than those for the planar-hyperbolic lens of FIG. 1(a) and elliptical-aspheric lens of FIG. 1(b). The secondary diffraction maxima arise due to the vignetting of the input beam at the lens but the magnitude of these maxima depends on the δ(r) relation.

Table 1 shows the FWHM for central diffraction maximum for all three lenses and both polarizations using a frequency of 0.7 THz. Simulations of loss-less lenses are included to indicate that the losses play only a minor role for determining the focal spot size. The numbers clearly show that the spot size using the symmetric-pass lens is more than 20% smaller compared with the other two lenses. Overall, the simulations predict a noticeable higher resolution when using the symmetric-pass lens but all three lenses produce a focal spot whose FWHM is smaller than one wavelength (0.44 mm).

The diffraction pattern has also been evaluated in the focal plane of an OAPM with an effective focal length of 25 mm and NA=1, and the spot size is similar to the one of the symmetric-pass lens. Note that such an OAPM is not suitable for any imaging application as any extended test material in between two OAPMs would obstruct the incident and the outgoing beam.

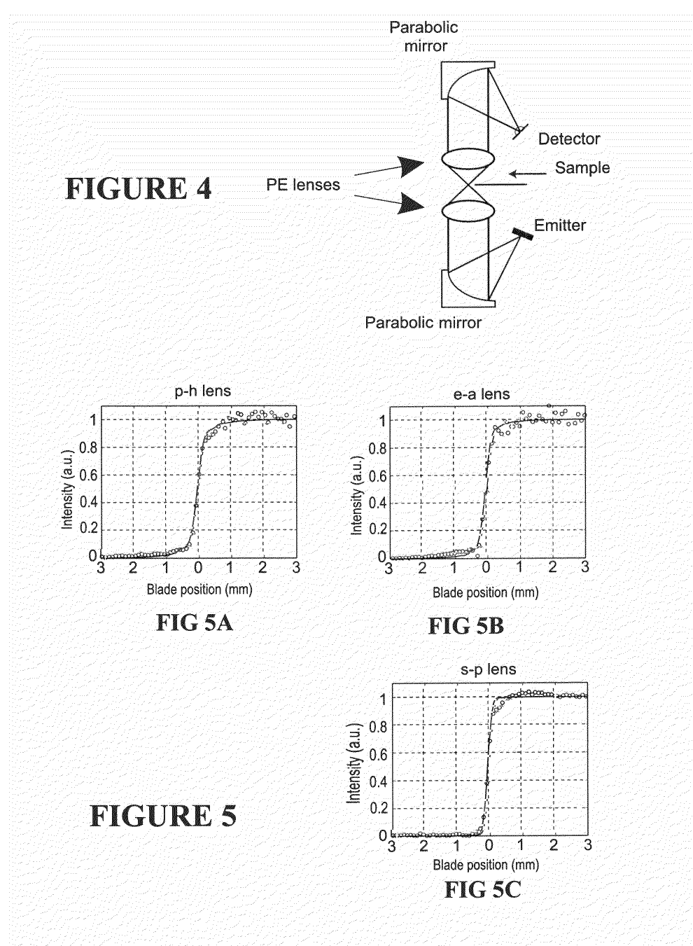

A THz time domain spectroscopy (THz-TDS) experimental setup as shown in FIG. 4 was used to verify the results from Kirchhoff's scalar diffraction theory.

The THz source is a surface emitter pumped by 80 fs, 800 nm pulses from a Ti:S laser, while the detector is a commercial THz antenna from EKSPLA which is gated by a time-delayed pulse from the same laser. The focal length of the OAPMs used to collimate and re-focus the THz beam was 75 mm. The current generated by the THz wave in the antenna was recorded with a lock-in amplifier, and the THz spectrum stretches from 0.1 THz to 1.5 THz with the peak at around 0.4 THz. The entire frequency range was evaluated with a single scan of the time delay between pump and probe pulses.

### Experiment 1

To evaluate the performance of a particular lens, a pair of identical lenses was inserted into the THz path with the second lens facing the opposite direction. First, a half-plane scan was used to determine the intensity distribution in the focal plane. For this purpose a razor blade was mounted as a ‘sample’ on a translation stage. It should be noted, however, that this method does not provide a perfect measurement of the focal spot sizes as a power meter with an active area large enough to capture the entire diffraction pattern was not used.

Other optical components in the experimental setup that were placed after the focal plane limit the beam size imaged on the antenna, which in turn does not integrate over a large area. Nevertheless, as is seen in FIG. 5, the measurement provides a very good indication of the focal spot size, and hence the spatial resolution for the imaging system.

Only the THz intensity at a frequency of 0.7 THz (using Fourier transformations) is shown so that the experimental results are readily compared with the simulations. FIG. 5 shows the experimental data for the three different lens pairs as well as the numerical integration using Equation (1) across the part of the beam profile in the focal plane (see FIG. 3) that is not covered by the half-plane. There are no fitted parameters, only the position of the optical axis was adjusted and the power of the fully transmitted beam was set to unity.

The agreement between theory and experiment is exceptional. Therefore sub-wavelengths resolution with the symmetric-pass lens producing the smallest spot size (see Table 1) has been achieved.

TABLE 1
Focal spot sizes determined from Kirchhoff's Scalar
Diffraction Theory.

| | Focal spot size, FWHM (mm) | | |
|---|---|---|---|
| Lens | Parallel | Perpendicular | a = 0 |
| Planar- | 0.372 | 0.383 | 0.378 |
| hyperbolic | | | |
| Elliptical- | 0.349 | 0.358 | 0.355 |
| aspheric | | | |
| Symmetric-pass | 0.269 | 0.279 | 0.276 |

### Experiment 2

In a second experiment, a double pinhole (two holes in a 80 μm-thick sheet of brass as a sample) was mounted. The holes have a diameter of 0.25 mm and are separated by 0.4 mm.

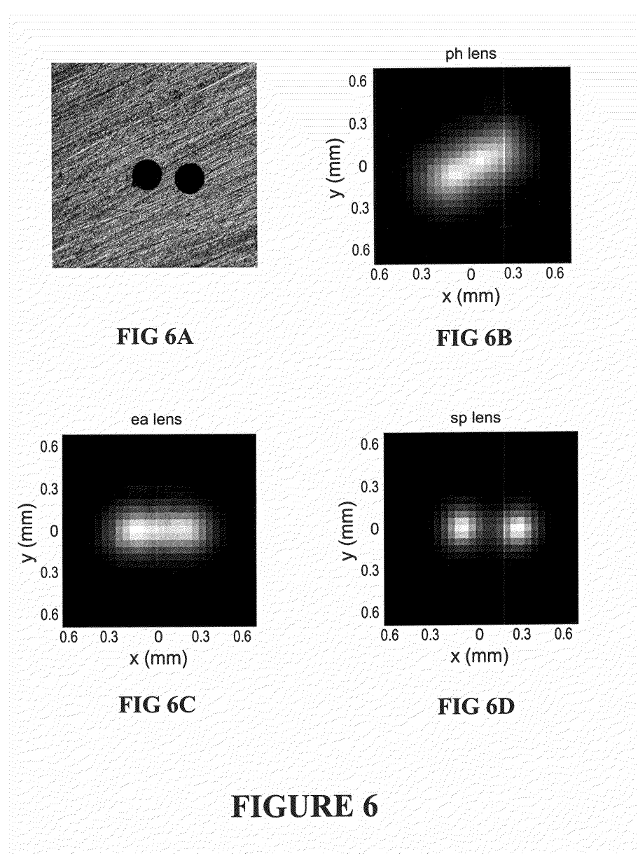

FIG. 6 shows a photo of the double pinhole and the THz image measured by performing x-y scans (with a step size of 50 μm in each direction) in the focal planes of the three different lenses. Shown is the THz intensity integrated over the entire spectral range with a central wavelength of 0.4 THz (λ=0.75 mm).

The experiments clearly show that the symmetric-pass lens pair shown in FIG. 6(d) gives the best resolution with an intensity at the saddle point between the two primary diffraction maxima of 30.8%. The values for the planar-hyperbolic lens pairs of FIG. 6(b) and the elliptical-aspheric lens pairs of FIG. 6(c) are 88.4% and 84.8%, respectively.

According to Rayleigh's criterion, the images of the two pin holes are resolved if the intensity at the saddle point is less than 81%. Therefore only the symmetric-pass lens pair clearly resolves the two pinholes. Using only the frequency component at 0.7 THz (λ=0.43 mm) the values for the saddle points are: (b) 86.8%, (c) 73.1%, and (d) 14.4%. Here both the elliptical-aspheric and the symmetric-pass lenses resolve the image but again the symmetric-pass lenses perform far better. As the separation between the two pinholes is 0.4 mm, this experiment conclusively demonstrates that sub-wavelength resolution can be achieved with the symmetric-pass lens pair.

While a fixed focal length of f=25 mm was used in the investigations, the lens designs can equally be applied to other focal lengths. The spot size in the focal plane was calculated using Kirchhoff's scalar diffraction theory, and the results were confirmed using a THz-TDS setup. The symmetric-pass lens performed by far the best, resulting in focal spot size (FWHM) of about 0.3 mm at a wavelength of 0.44 mm, and very clearly resolving two pinholes that are separated by 0.53%.

The term “comprising” as used in this specification means “consisting at least in part of”. Related terms such as “comprise” and “comprised” are to be interpreted in the same manner.

This invention may also be said broadly to consist in the parts, elements and features referred to or indicated in the specification of the application, individually or collectively, and any or all combinations of any two or more of said parts, elements or features, and where specific integers are mentioned herein which have known equivalents in the art to which this invention relates, such known equivalents are deemed to be incorporated herein as if individually set forth.

1. A lens for Terahertz imaging comprising a transparent body defining at least a first and a second lens surface, said body arranged such that light incident to said lens refracts at said first lens surface, propagates through said body to said second lens surface and refracts at said second lens surface, wherein the angle of deviation of light at said first lens surface substantially equals the angle of deviation of light at said second lens surface.

2. A lens as claimed in claim 1 wherein said first lens surface of said transparent body is defined by a first surface contour and said second lens surface of said transparent body is defined by a second surface contour.

3. A lens as claimed in claim 2 wherein said first surface contour and said second surface contour are numerically calculated to form a symmetric-pass lens.

4. A lens as claimed in claim 1 wherein said transparent body is made of a highly transparent polymer.

5. A method of producing a lens comprising:
selecting a lens focal length,
selecting a lens numerical aperture,
selecting a lens diameter,
numerically deriving the coordinates of a first lens surface in relation to the coordinates of a second lens surface such that the angle of deviation of light at said first lens surface will substantially equal the angle of deviation of light at said second lens surface, and
cutting a transparent body of material having first and second surfaces according to said first and second lens surface coordinates, said surfaces arranged such that light incident to said lens will propagate from said first surface to said second surface.

6. A Terahertz imaging system comprising:
a Terahertz light source, said light source arranged to output light to a lens, said lens further comprising a transparent body defining at least a first and a second lens surface, said body arranged such that light incident to said lens refracts at said first lens surface, propagates through said body to said second lens surface and refracts at said second lens surface, wherein the angle of deviation of light at said first lens surface substantially equals the angle of deviation of light at said second lens surface, and
a Terahertz light detector, said detector arranged to receive light from said lens.
